(19) United States
(12) Patent Application Publication
(10) Pub. No.: US 2023/0005976 A1
(43) Pub. Date: Jan. 5, 2023

(54) IMAGING DEVICE

(71) Applicant: HITACHI ASTEMO, LTD., Hitachinaka-shi, Ibaraki (JP)

(72) Inventors: Kenichi TAKEUCHI, Hitachinaka-shi, Ibaraki (JP); Hidenori SHINOHARA, Hitachinaka-shi, Ibaraki (JP); Takeshi HAGA, Hitachinaka-shi, Ibaraki (JP); Seiichi KATOU, Tokyo (JP)

(73) Assignee: HITACHI ASTEMO, LTD., Hitachinaka-shi, Ibaraki (JP)

(21) Appl. No.: 17/782,133

(22) PCT Filed: Dec. 15, 2020
(86) PCT No.: PCT/JP2020/046667

§ 371 Date: Jun. 2, 2022

(30) Foreign Application Priority Data
Jan. 22, 2020 (JP) 2020-007967

(51) Int. Cl. H01L 27/146; H01L 23/367; H01L 31/024; H04N 5/225

(52) U.S. Cl. CPC H01L 27/14618; H01L 23/3672; H01L 27/14634; H01L 31/024; H04N 5/2253; H04N 5/22521

(57) ABSTRACT

Provided is an imaging device capable of efficiently dissipating heat from an imaging element. An imaging device 100 includes: an imaging element substrate 4 on which an insulating layer 51 and a conductor layer 52 are stacked and an imaging element 41 is mounted; and a housing 1 that accommodates the imaging element substrate 4. The surface of the imaging element substrate 4 has a mounting region 45 on which an electronic component 43 including the imaging element 41 is mounted, a covered region 46 in which the conductor layer 52 is covered with the insulating layer 51, and an exposed region 47 in which the conductor layer 52 is exposed from the insulating layer 51, and the exposed region 47 is connected to the housing 1.

### TECHNICAL FIELD

The present invention relates to an imaging device.

### BACKGROUND ART

Conventionally, there is known an invention related to an imaging device mounted on a vehicle or the like (for example, PTL 1).

PTL 1 describes that a camera board provided in an imaging device includes: a sensor-arrangement region in which an image sensor is arranged; and a dissipator region with which a thermal transfer member that transfers heat generated in the image sensor to a case is disposed in contact.

### CITATION LIST

### Patent Literature

PTL 1: JP 2016-208125 A

### SUMMARY OF INVENTION

### Technical Problem

In the imaging device described in PTL 1, a surface of the dissipator region of the camera board is covered with a solder-resist layer, and the thermal transfer member that transfers the heat generated in the image sensor to the case is disposed in contact with the solder-resist layer. The solder-resist layer has lower thermal conductivity than a conductor pattern of the camera board. Even if the heat generated in the image sensor is transferred to the dissipator region of the camera board, the amount of heat transferred to the thermal transfer member through the solder-resist layer is limited, and most of the amount of heat transferred to the dissipator region is diffused along a wiring pattern of the dissipator region. Therefore, the imaging device described in PTL 1 has room for improvement in terms of efficiently dissipating heat from the image sensor.

The present invention has been made in view of the above, and an object thereof is to provide an imaging device capable of efficiently dissipating heat from an imaging element.

### Solution to Problem

In order to solve the above problem, an imaging device according to the present invention includes: an imaging element substrate on which an insulating layer and a conductor layer are stacked and an imaging element is mounted; and a housing which accommodates the imaging element substrate. A surface of the imaging element substrate has a mounting region on which an electronic component including the imaging element is mounted, a covered region in which the conductor layer is covered with the insulating layer, and an exposed region in which the conductor layer is exposed from the insulating layer, and the exposed region is connected to the housing.

### Advantageous Effects of Invention

According to the present invention, it is possible to provide the imaging device capable of efficiently dissipating heat from the imaging element.

Other objects, configurations, and effects which have not been described above will become apparent from embodiments to be described hereinafter.

### BRIEF DESCRIPTION OF DRAWINGS

FIG. 1 is a view illustrating an appearance of an imaging device according to the present embodiment.

FIG. 2 is an exploded perspective view of the imaging device illustrated in FIG. 1.

FIG. 3 is a view of the imaging device illustrated in FIG. 1 as viewed from the rear side.

FIG. 4 is a view of a housing and a pair of camera modules illustrated in FIG. 2 as viewed from the rear side.

FIG. 5 is an enlarged view of the camera module illustrated in FIG. 2.

FIG. 6 is an exploded perspective view of the camera module illustrated in FIG. 5.

FIG. 7 is a view illustrating an internal configuration of the imaging device in the vicinity of a connection portion illustrated in FIG. 1.

FIG. 8 is a schematic view illustrating a stacked structure and an exposed region of an imaging element substrate.

FIG. 9 is a schematic view illustrating a first modification of the exposed region of the imaging element substrate.

FIG. 10 is a schematic view illustrating a second modification of the exposed region of the imaging element substrate.

### DESCRIPTION OF EMBODIMENTS

Hereinafter, embodiments of the present invention will be described with reference to the drawings. Note that configurations denoted by the same reference signs in the respective embodiments have similar functions in the respective embodiments unless otherwise specified, and thus, the description thereof will be omitted. Further, orthogonal coordinate axes including an x axis, a y axis, and a z axis are described in the necessary drawings in order to clarify the description of the position of each unit.

In the present embodiment, an optical axis direction OA of a lens unit 3 provided in an imaging device 100 is also referred to as a “front-rear direction”. The “front side” is a direction toward a subject from the lens unit 3. The “front side” corresponds to the positive direction of the z axis among the orthogonal coordinate axes described in the drawings, and corresponds to a forward direction of a vehicle in a state in which the imaging device 100 is installed in the vehicle. The “rear side” is the opposite direction of the front side. The “rear side” corresponds to the negative direction of the z axis among the orthogonal coordinate axes described in the drawings, and corresponds to a backward direction of the vehicle in a state in which the imaging device 100 is installed in the vehicle.

In the present embodiment, a direction extending vertically when the imaging device 100 is viewed from the rear side to the front side is also referred to as an “up-down direction”. The “upper side” is a direction directed upward when the imaging device 100 is viewed from the rear side to the front side. The “upper side” corresponds to the positive direction of the y axis among the orthogonal coordinate axes described in the drawings, and corresponds to the opposite direction of the gravity direction in a state in which the imaging device 100 is installed in the vehicle. The “lower side” is the opposite direction of the upper side. The “lower side” corresponds to the negative direction of the y axis among the orthogonal coordinate axes described in the drawings, and corresponds to the gravity direction in a state in which the imaging device 100 is installed in the vehicle.

In the present embodiment, a direction extending laterally when the imaging device 100 is viewed from the rear side to the front side is also referred to as a “left-right direction”. The “left side” is a direction toward the left when the imaging device 100 is viewed from the rear side to the front side. The “left side” corresponds to the positive direction of the x axis among the orthogonal coordinate axes described in the drawings, and corresponds to a direction toward the left when the vehicle is viewed from the rear side to the front side in a state in which the imaging device 100 is installed in the vehicle. The “right side” is a direction opposite to the left side. The “right side” corresponds to the negative direction of the x axis among the orthogonal coordinate axes described in the drawings, and corresponds to a direction toward the right when the vehicle is viewed from the rear side to the front side in a state in which the imaging device 100 is installed in the vehicle.

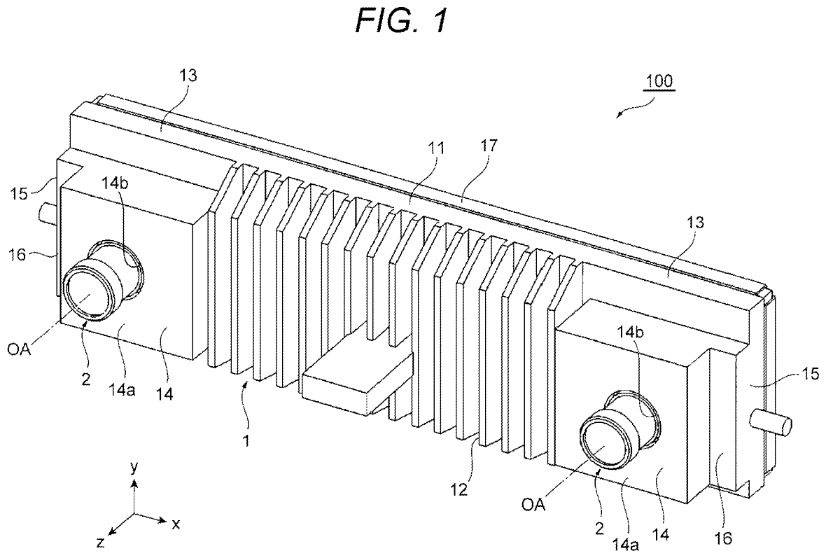

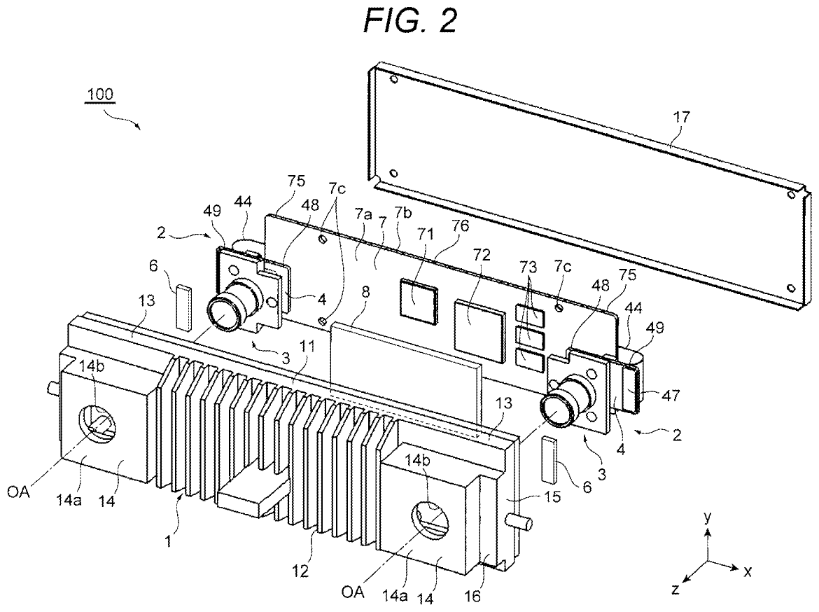

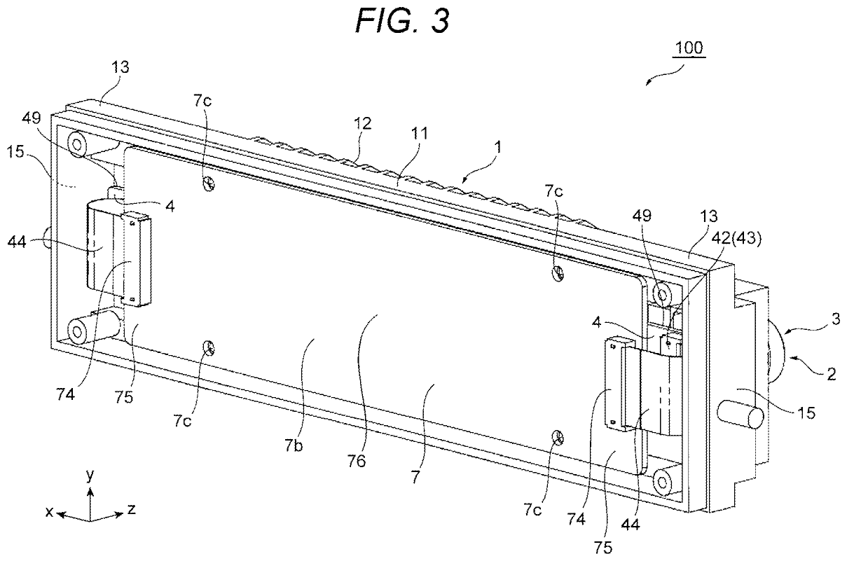

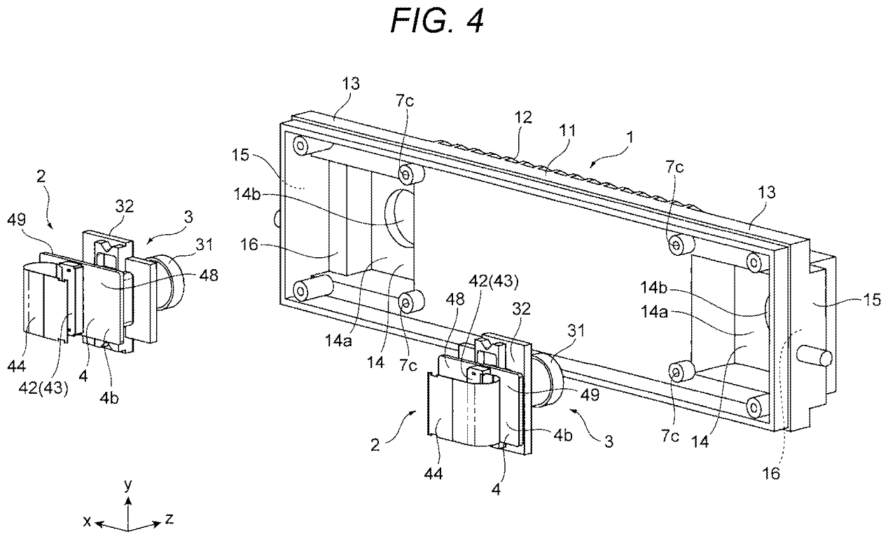

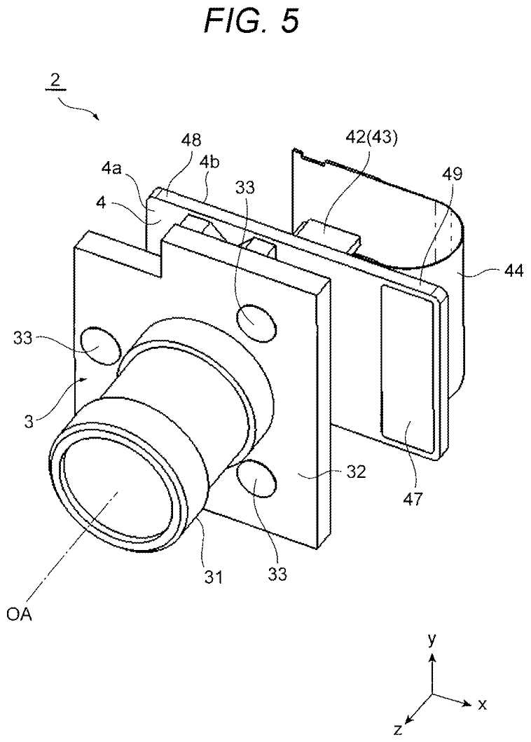

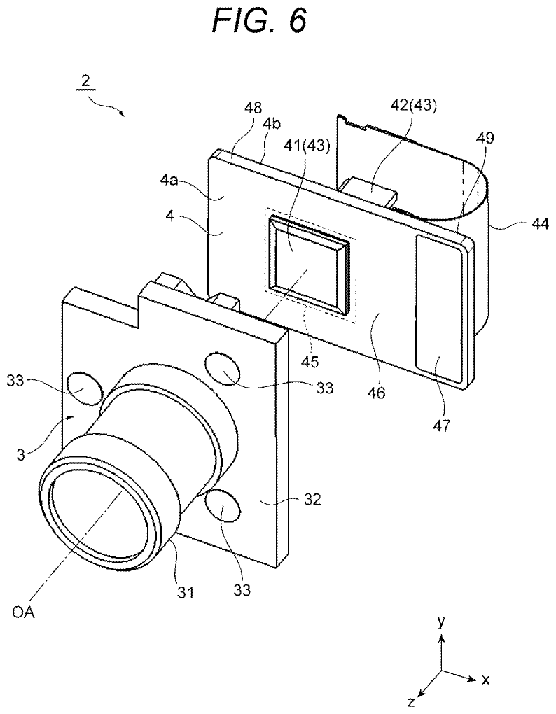

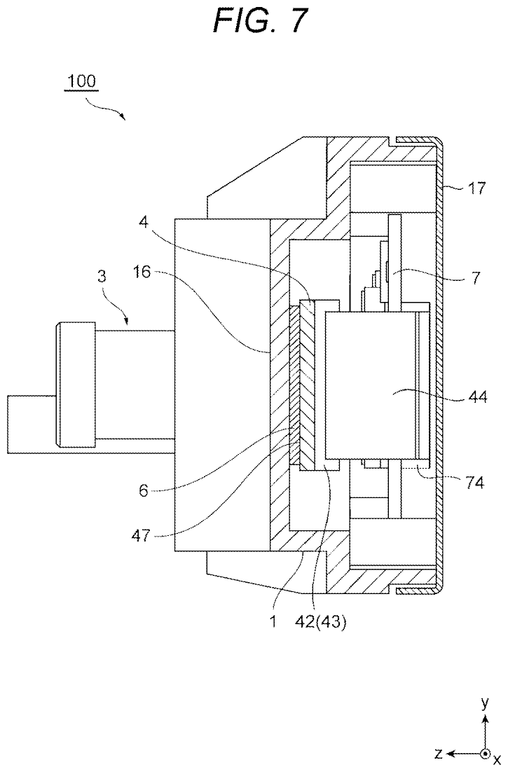

FIG. 1 is a view illustrating an appearance of the imaging device 100 according to the present embodiment. FIG. 2 is an exploded perspective view of the imaging device 100 illustrated in FIG. 1. FIG. 3 is a view of the imaging device 100 illustrated in FIG. 1 as viewed from the rear side. FIG. 4 is a view of a housing 1 and a pair of camera modules 2 illustrated in FIG. 2 as viewed from the rear side. FIG. 5 is an enlarged view of the camera module 2 illustrated in FIG. 2. FIG. 6 is an exploded perspective view of the camera module 2 illustrated in FIG. 5. FIG. 7 is a view illustrating an internal configuration of the imaging device 100 in the vicinity of a connection portion 16 illustrated in FIG. 1. Note that FIG. 3 does not illustrate a cover 17.

The imaging device 100 is, for example, a stereo camera that is installed on the inner side of a windshield glass of a vehicle, such as an automobile, toward the front side in a traveling direction and captures an image of a subject such as a road, a preceding vehicle, an oncoming vehicle, a pedestrian, or an obstacle. The imaging device 100 can simultaneously capture images of a subject by the pair of camera modules 2, obtain parallax from the pair of acquired images, and measure a distance to the subject, a relative speed, and the like. The measurement results are transmitted from the imaging device 100 to a control device of the vehicle, and are used for processing for controlling traveling, braking, and the like of the vehicle.

As illustrated in FIG. 2, the imaging device 100 includes the housing 1, the pair of camera modules 2 that captures the images of the subject, and a signal processing substrate 7 on which circuit elements 71 to 73 that process an output signal of the imaging element 41 are mounted.

As illustrated in FIGS. 2 and 3, the housing 1 accommodates the pair of camera modules 2 and the signal processing substrate 7, and plays a role of dissipating heat generated in the pair of camera modules 2 and the signal processing substrate 7 to the outside. The housing 1 is a metal housing having a box shape that is long in the left-right direction, and is manufactured by, for example, aluminum die casting or the like. The housing 1 is covered from the rear side by the cover 17 in the state of accommodating the pair of camera modules 2 and the signal processing substrate 7.

The cover 17 is made of a metal plate such as an aluminum plate.

As illustrated in FIGS. 1 to 4, the housing 1 has an intermediate portion 11 located between both end portions 13 in the left-right direction. A heat dissipation fin 12 is provided in the intermediate portion 11. The heat dissipation fin 12 is configured by arranging a plurality of heat dissipation plates extending in the up-down direction at intervals along the left-right direction.

As illustrated in FIGS. 1, 2, and 4, a pair of attachment portions 14 to which the pair of camera modules 2 is attached is provided at both the end portions 13 of the housing 1 in the left-right direction. Each of the pair of attachment portions 14 has a rectangular box shape and has a front surface portion 14a facing the front side. The front surface portion 14a is orthogonal to the optical axis direction OA, and is provided with a through-hole 14b into which the lens unit 3 of the camera module 2 is inserted.

A pair of connection portions 16 is provided at both the end portions 13 of the housing 1 in the left-right direction. As will be described later, a pair of imaging element substrates 4 is connected to the pair of connection portions 16. The pair of connection portions 16 is arranged with an interval along the left-right direction. Each of the pair of connection portions 16 is provided between a side surface portion 15, which is each end surface of the housing 1 in the left-right direction, and the attachment portion 14. That is, each of the pair of connection portions 16 is arranged on the outer side of the attachment portion 14 in an outward direction from the intermediate portion 11 toward the end portion 13 of the housing 1. Each of the pair of connection portions 16 has a flat plate shape along the left-right direction and is orthogonal to the optical axis direction OA. Note that the side surface portion 15 may be a part of the end portion 13.

Each of the pair of camera modules 2 is attached to the attachment portion 14 of the housing 1 in a state in which the lens unit 3 facing the front side is inserted into the through-hole 14b of the attachment portion 14. The pair of camera modules 2 is attached in a state of providing an interval corresponding to a length of a base line connecting the pair of camera modules 2 in the left-right direction. Each of the pair of camera modules 2 is attached in a state in which rotational deviation around the optical axis direction OA is adjusted, that is, in a state in which a roll angle of the lens 31 is appropriate.

As illustrated in FIGS. 2 and 4, each of the pair of camera modules 2 includes: the lens unit 3 that is an imaging optical system of the camera module 2; and the imaging element substrate 4 which is a circuit board on which an electronic component 43 including the imaging element 41 and a connector 42 is mounted. That is, the pair of lens units 3 included in the pair of camera modules 2 is arranged at an interval along the left-right direction. The pair of imaging element substrates 4 included in the pair of camera modules 2 is arranged at an interval along the left-right direction.

As illustrated in FIGS. 5 and 6, the lens unit 3 includes a lens 31 and a flange portion 32 that holds the lens 31 and is connected to the imaging element substrate 4.

The lens 31 forms a subject image on a light receiving surface of the imaging element 41 mounted on the imaging element substrate 4. A lens barrel of the lens 31 may be made of resin.

The flange portion 32 has a plate shape that is orthogonal to the optical axis direction OA and extends along the up-down direction and the left-right direction. A tubular portion that holds the lens barrel of the lens 31 is formed at a central portion of the flange portion 32. The flange portion 32 is provided with a reference surface 33 that is orthogonal to the optical axis direction OA and serves as a reference for position adjustment of the lens 31. When the camera module 2 is attached to the housing 1, the reference surface 33 is in contact with the front surface portion 14a of the attachment portion 14 to regulate the position of the camera module 2 in the optical axis direction OA.

As illustrated in FIG. 6, the imaging element substrate 4 has a front surface 4a which is a surface on which the imaging element 41 is mounted, and a back surface 4b which is a surface opposite to the front surface 4a in the optical axis direction OA. The front surface 4a of the imaging element substrate 4 is a surface of the imaging element substrate 4 on the front side, and the back surface 4b of the imaging element substrate 4 is a surface of the imaging element substrate 4 on the rear side. The front surface 4a and the back surface 4b of the imaging element substrate 4 are major surfaces having a large area among the respective surfaces constituting the imaging element substrate 4, and are surfaces orthogonal to the optical axis direction OA. The imaging element substrate 4 is adjusted in position such that the subject image having passed through the lens 31 is formed on the light receiving surface of the imaging element 41, and then, is bonded to the flange portion 32 of the lens unit 3.

As illustrated in FIGS. 2 and 4 to 6, the imaging element substrate 4 has end portions 48 and 49 in the left-right direction. The end portions 48 and 49 are end portions located in an outward direction from the circuit elements 71 to 73 toward the imaging element 41 as viewed in the optical axis direction OA. The end portions 48 and 49 include a first end portion 48 close to the circuit elements 71 to 73 and a second end portion 49 far from the circuit elements 71 to 73 in this outward direction. In other words, each of the pair of imaging element substrates 4 includes: the first end portion 48 located in the outward direction from the circuit elements 71 to 73 toward the imaging element 41 as viewed in the optical axis direction OA; and the second end portion 49 located on the outer side of the first end portion 48 in the outward direction from the circuit elements 71 to 73 toward the imaging element 41. Each of the pair of second end portions 49 included in the pair of imaging element substrates 4 is arranged to face each of the pair of connection portions 16 with an interval along the optical axis direction OA.

The imaging element 41 includes an image sensor such as a complementary metal oxide semiconductor (CMOS) or a charge coupled device (CCD). As illustrated in FIG. 6, the imaging element 41 is mounted on each of the pair of imaging element substrates 4. The pair of imaging elements 41 mounted on the pair of imaging element substrates 4 is arranged at an interval along the left-right direction.

The imaging element 41 is connected to the connector 42 mounted on the back surface 4b of the imaging element substrate 4.

As illustrated in FIGS. 3 and 7, the connector 42 is connected to a connector 74 mounted on the signal processing substrate 7 through a wiring member 44 having flexibility such as a flexible printed circuit (FPC) or a flexible flat cable (FFC).

As illustrated in FIG. 2, the signal processing substrate 7 has a front surface 7a which is a surface on which the circuit elements 71 to 73 are mounted, and a back surface 7b which is a surface opposite to the front surface 7a in the optical axis direction OA. The front surface 7a of the signal processing substrate 7 is a surface of the signal processing substrate 7 on the front side, and the back surface 7b of the signal processing substrate 7 is a surface of the signal processing substrate 7 on the rear side. The front surface 7a and the back surface 7b of the signal processing substrate 7 are major surfaces having a large area among the respective surfaces constituting the signal processing substrate 7, and are surfaces orthogonal to the optical axis direction OA. The signal processing substrate 7 is arranged to face the back surface 4b of the imaging element substrate 4 with an interval on the rear side of the imaging element substrate 4. The signal processing substrate 7 is attached to the housing 1 by a fastening member such as a screw. An attaching position 7c of the signal processing substrate 7 with respect to the housing 1 is located between the pair of imaging element substrates 4 and the circuit elements 71 to 73 as viewed in the optical axis direction OA.

The circuit elements 71 to 73 includes a first circuit element 71, a second circuit element 72, and a third circuit element 73. The first circuit element 71 is an integrated circuit that processes a captured image indicated by an image signal that is an output signal of the imaging element 41, and includes a field programmable gate array (FPGA) or the like. The second circuit element 72 is a processor that performs various types of signal processing and arithmetic processing, and includes a micro processing unit (MPU) or the like. The third circuit element 73 includes a memory or the like used for temporary storage of data or a program.

The circuit elements 71 to 73 are mounted on an intermediate portion 76 between both end portions 75 of the signal processing substrate 7 in the left-right direction. The circuit elements 71 to 73 are arranged between the pair of imaging elements 41 arranged at an interval along the left-right direction as viewed in the optical axis direction OA.

The circuit elements 71 to 73 are circuit elements each having a large amount of heat generation that requires heat dissipation in the housing 1 and the like. The circuit elements 71 to 73 are connected to the intermediate portion 11 of the housing 1 through an intermediate member 8 having thermal conductivity. The intermediate member 8 can be made of a thermal transfer member such as a gel, a sheet, or grease having thermal conductivity, but is not particularly limited thereto.

The circuit elements 71 to 73 are connected to the connector 74 mounted on the back surface 7b of the signal processing substrate 7. As illustrated in FIGS. 3 and 7, the connector 74 is connected to the connector 42 mounted on the imaging element substrate 4 through the wiring member 44. Note that the circuit elements 71 to 73 are not limited to the circuit elements described above.

With the above configuration, when the camera module 2 captures an image of a subject in the imaging device 100, the imaging element 41 of the camera module 2 outputs an image signal corresponding to the captured image to the imaging element substrate 4. The image signal output to the imaging element substrate 4 passes through a wiring pattern of the imaging element substrate 4, the connector 42, and the wiring member 44, and then, is input from the connector 74 to the signal processing substrate 7. The image signal input to the signal processing substrate 7 is input to the circuit elements 71 to 73 through a wiring pattern of the signal processing substrate 7. The circuit elements 71 to 73 perform image processing on the captured image indicated by the input image signal, performs stereo matching processing or the like to measure a distance to the subject, or performs pattern matching processing or the like to perform image recognition.

During the operation of the imaging device 100 as described above, the imaging element 41 and the circuit elements 71 to 73 generate heat. The amount of heat generation of the circuit elements 71 to 73 is larger than the amount of heat generation of the imaging element 41. The circuit elements 71 to 73 are connected to the housing through the signal processing substrate 7 and the intermediate member 8. The heat generated in the circuit elements 71 to 73 is mainly transferred to the housing 1 and dissipated to the outside.

Here, in a case where the number of pixels of the imaging element 41 is small as in the conventional imaging device 100, the amount of heat generation of the imaging element 41 is small, and a temperature rise thereof is also small. In recent years, however, the number of pixels of the imaging element 41 tends to greatly increase in the imaging device 100, the amount of heat generation tends to greatly increase, and the temperature rise also tends to increase. A reason why the number of pixels of the imaging element 41 tends to increase is that there is a demand for enhancement in the angle of view of the imaging device 100, such as widening the angle of view in the left-right direction to cope with jumping-out of a pedestrian or a bicycle required by a new car assessment program (NCAP). In addition, it is also necessary to improve the accuracy in image recognition of a subject, and there is a demand for an increase in the accuracy and speed of the imaging device 100.

Most of the heat generated in the imaging element 41 is transferred to the imaging element substrate 4 on which the imaging element 41 is mounted, and most of the heat transferred to the imaging element substrate 4 is diffused through the wiring pattern of the imaging element substrate 4. That is, most of the heat generated in the imaging element 41 is diffused through the wiring pattern of the imaging element substrate 4. It is important how to transfer the heat, which has been transferred to the imaging element substrate 4, to the housing 1 in order to suppress the temperature rise of the imaging element 41.

A path for transferring the heat generated in the imaging element substrate 4 from the lens unit 3 to the housing 1 is conceivable as a heat transfer path from the imaging element substrate 4 to the housing 1. This heat transfer path from the lens unit 3 has a limited heat transfer effect because the lens barrel of the lens 31 is made of resin and has a low thermal conductivity. Moreover, the lens barrel of the lens 31 and the imaging element substrate 4 need to be supported in the air such that three-dimensional position adjustment can be performed. Only a gap or an adhesive is present between the lens barrel of the lens 31 and the imaging element substrate 4. Even if the lens barrel of the lens 31 is made of metal, it is difficult to expect that the heat transferred to the imaging element substrate 4 is made to be transferred to the housing 1 through the lens barrel of the lens 31.

Therefore, the heat generated in the imaging element 41 is efficiently transferred from the imaging element substrate 4 to the housing 1 by connecting an exposed region 47 to be described later, provided in the imaging element substrate 4, to the housing 1 in the imaging device 100 according to the present embodiment.

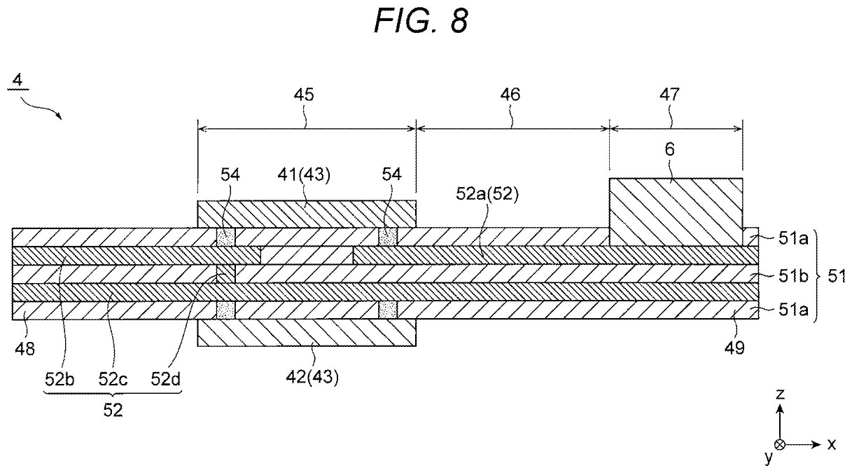

FIG. 8 is a schematic view illustrating a stacked structure and the exposed region 47 of the imaging element substrate 4.

As illustrated in FIG. 8, the imaging element substrate 4 has a multilayer structure in which an insulating layer 51 and a conductor layer 52 are stacked. The insulating layer 51 is the outermost layer of the imaging element substrate 4, and includes a first insulating layer 51a made of an insulating film such as solder resist, and a second insulating layer 51b which is a layer inside the imaging element substrate 4 and is made of an insulating base material such as a glass epoxy base material.

The conductor layer 52 is a layer including a metal foil such as a copper foil, and is a layer on which the wiring pattern of the imaging element substrate 4 is formed. The conductor layer 52 has a higher thermal conductivity than the insulating layer 51. The conductor layer 52 includes a first conductor layer 52a having a ground wiring pattern, a second conductor layer 52b and a third conductor layer 52c having a wiring pattern other than the ground, and a via 52d that allows conduction between the respective layers of the conductor layer 52. Note that the conductor layer 52 may be made of a metal foil formed using a metal material other than copper.

As illustrated in FIGS. 6 and 8, the surface of the imaging element substrate 4 has a mounting region 45, a covered region 46, and an exposed region 47. The mounting region 45 is a region where the electronic component 43 including the imaging element 41 and the connector 42 is mounted on the imaging element substrate 4. In the mounting region 45, the electronic component 43 is bonded to the conductor layer 52 through a bonding material 54 such as solder. The covered region 46 is a region where the conductor layer 52 is covered with the insulating layer 51. The exposed region 47 is a region where the conductor layer 52 is exposed from the insulating layer 51 differently from the mounting region 45 and the covered region 46. The exposed region 47 is orthogonal to the optical axis direction OA and is connected to the connection portion 16 of the housing 1.

The exposed region 47 can be easily formed, for example, only by peeling the first insulating layer 51a as the outermost layer, made of the insulating film such as solder resist, and exposing the conductor layer 52 to the surface of the imaging element substrate 4. Alternatively, the exposed region 47 can also be formed by not previously covering a portion of the conductor layer 52 to be exposed on the surface of the imaging element substrate 4 with the first insulating layer 51a.

The conductor layer 52 exposed in the exposed region 47 may be the first conductor layer 52a having the ground wiring pattern or the conductor layer 52 electrically connected to the first conductor layer 52a. When the conductor layer 52 exposed in the exposed region 47 is the conductor layer 52 having the same potential as the ground, an electrical defect such as electric leakage does not occur, which is preferable.

Since the exposed region 47 is provided in the conductor layer 52 having the same potential as the ground, the imaging element substrate 4 can easily expose the conductor layer 52 having a high thermal conductivity while securing the electrical function of the imaging element substrate 4. Further, the imaging element substrate 4 can also use the wiring pattern constituting an electric circuit of the imaging element substrate 4 for the heat transfer to the housing 1.

With the above configuration, the imaging device 100 according to the present embodiment can connect the conductor layer 52 of the imaging element substrate 4 through which most of the heat generated in the imaging element 41 passes to the housing 1 without intervention of the insulating layer 51 having a low thermal conductivity. As a result, the imaging device 100 can efficiently transfer the heat generated in the imaging element 41 to the housing 1. Therefore, the imaging device 100 can efficiently dissipate heat from the imaging element 41.

Here, the circuit elements 71 to 73 each having a large amount of heat generation are connected to the intermediate portion 11 of the housing 1 through the intermediate member 8 in the imaging device 100. The housing 1 has a temperature distribution such that sites of the intermediate portion 11 of the housing 1 to which the circuit elements 71 to 73 are connected has the highest temperature, and the temperature becomes lower as a distance from the connection sites of the circuit elements 71 to 73 increases in the outward direction.

A reason for having such a temperature distribution is that the amount of heat that can be dissipated by the housing 1 exceeds the amount of heat transferred to the housing 1 as the distance from the connection sites of the circuit elements 71 to 73 increases in the outward direction. In consideration of such a temperature distribution, when heat is transferred from the imaging element substrate 4 to the housing 1 in the end portion 13 of the housing 1 away from the connection sites of the circuit elements 71 to 73 in the outward direction, the heat generated in the imaging element 41 can be more efficiently transferred to the housing 1.

In particular, the heat dissipation fin 12 provided in the intermediate portion 11 in the housing 1 has the structure in which the heat dissipation plates extending in the up-down direction are arranged at intervals in the left-right direction. The housing 1 has a structure in which it is easy to take in fresh air from the lower side of the housing 1 and discharge the air to the upper side of the housing 1, and the temperature of the lower side of the end portion 13 is lower than that of the upper side of the end portion 13. Therefore, when heat is transferred from the imaging element substrate 4 to the housing 1 at least on the lower side of the end portion 13 of the housing 1, the heat generated in the imaging element 41 can be efficiently transferred to the housing 1.

In the imaging device 100 according to the present embodiment, the exposed region 47 of each of the pair of imaging element substrates 4 is provided in the second end portion 49 located on the outer side of the first end portion 48 in the outward direction from the circuit elements 71 to 73 toward the imaging element 41 as illustrated in FIG. 2. Further, the exposed region 47 is connected to the connection portion 16 provided in the end portion 13 of the housing 1 in the outward direction.

With the above configuration, the exposed region 47 provided in the imaging element substrate 4 is connected to the connection portion 16 of the housing 1 having a relatively low temperature in the imaging device 100 according to the present embodiment. As a result, the imaging device 100 can efficiently transfer the heat, which has been transferred from the imaging element 41 to the imaging element substrate 4, to the housing 1. Therefore, the imaging device 100 can more efficiently dissipate the heat from the imaging element 41.

Further, in the imaging device 100 according to the present embodiment, the exposed region 47 provided on the imaging element substrate 4 includes the conductor layer 52 having the wiring pattern constituting the electric circuit of the imaging element substrate 4 as illustrated in FIG. 8.

With the above configuration, it is unnecessary to specially provide the conductor layer 52 of the imaging element substrate 4 to be used for heat transfer to the housing 1 in the imaging device 100 according to the present embodiment, and thus, the exposed region 47 can be easily provided. As a result, the heat transferred from the imaging element 41 to the imaging element substrate 4 can be efficiently and easily transferred to the housing 1 in the imaging device 100. Therefore, the imaging device 100 can efficiently and easily dissipate the heat from the imaging element 41.

Further, the exposed regions 47 of the pair of imaging element substrates 4 are connected to the connection portions 16 of the housing 1 through intermediate members 6 each having thermal conductivity in the imaging device 100 according to the present embodiment as illustrated in FIGS. 2 and 7. The intermediate member 6 can be made of a thermal transfer member such as a gel, a sheet, or grease having thermal conductivity, but is not particularly limited thereto.

With the above configuration, in the imaging device 100 according to the present embodiment, the exposed region 47 and the connection portion 16 can be connected in closer contact with each other without significantly changing the shape of the imaging element substrate 4 or the housing 1. As a result, the imaging device 100 can more efficiently transfer the heat, which has been transferred from the imaging element 41 to the imaging element substrate 4, to the housing 1. Therefore, the imaging device 100 can more efficiently dissipate the heat from the imaging element 41.

Further, the second end portion 49 of the imaging element substrate 4 provided with the exposed region 47 is arranged on the outer side of the end portion 75 of the signal processing substrate 7 in the imaging device 100 according to the present embodiment as illustrated in FIG. 2.

With the above configuration, in the imaging device 100 according to the present embodiment, the exposed region 47 can be separated in the outward direction from the circuit elements 71 to 73 having a large amount of heat generation and the signal processing substrate 7 on which the circuit elements 71 to 73 are mounted. In the imaging device 100, the exposed region 47 is hardly affected by the heat of the circuit elements 71 to 73 and the signal processing substrate 7. As a result, the heat transferred from the imaging element 41 to the imaging element substrate 4 can be more efficiently transferred to the housing 1 in the imaging device 100. Therefore, the imaging device 100 can more efficiently dissipate the heat from the imaging element 41.

Further, the exposed region 47 of each of the pair of imaging element substrates 4 is orthogonal to the optical axis direction OA, and is arranged to face each of the pair of connection portions 16 with an interval in the optical axis direction OA in the imaging device 100 according to the present embodiment as illustrated in FIG. 2. Further, the intermediate member 6 is provided for the interval between each of the exposed regions 47 of the pair of imaging element substrates 4 and each of the pair of connection portions 16. That is, the intermediate member 6 is provided with respect to the interval between the exposed region 47 and the connection portion 16 which are orthogonal to the optical axis direction OA and parallel to each other in the imaging device 100.

With the above configuration, the thickness of the intermediate member 6 is constant in the optical axis direction OA in the imaging device 100 according to the present embodiment. As a result, the heat transferred from the imaging element 41 to the imaging element substrate 4 can be more efficiently transferred to the housing 1 in the imaging device 100. Therefore, the imaging device 100 can more efficiently dissipate the heat from the imaging element 41.

In particular, when the camera module 2 is attached to the housing 1 in the imaging device 100, the position adjustment of the camera module 2 in the optical axis direction OA is performed, and then, position adjustment in the up-down direction and the left-right direction and position adjustment in a rotation direction around the optical axis direction OA are performed. Since the exposed region 47 and the connection portion 16 are orthogonal to the optical axis direction OA and parallel to each other in the imaging device 100, the interval between exposed region 47 and connection portion 16 can be kept constant even in such a case where the position adjustment is performed in the up-down direction, the left-right direction, and the rotation direction. As a result, the imaging device 100 can keep the thickness of the intermediate member 6 constant in the optical axis direction OA even when the position adjustment is performed in the up-down direction and the left-right direction. Thus, the heat transferred from the imaging element 41 to the imaging element substrate 4 can be efficiently and stably transferred to the housing 1. Therefore, the imaging device 100 can efficiently and stably dissipate the heat from the imaging element 41.

### [Modification of Exposed Region]

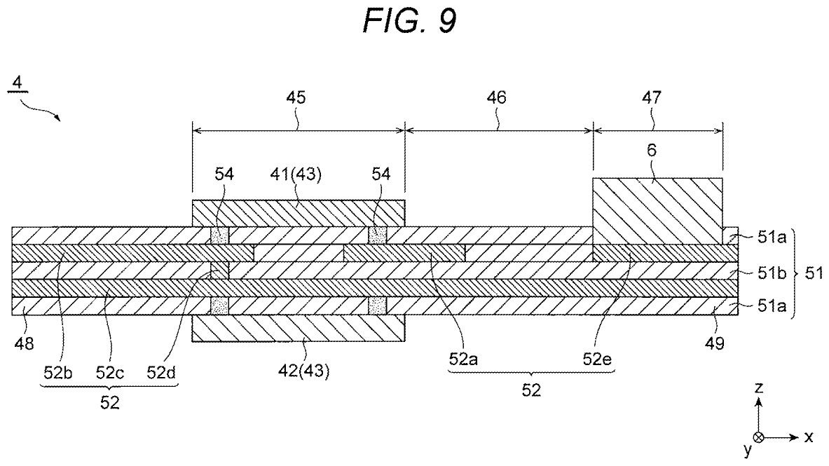

FIG. 9 is a schematic view illustrating a first modification of the exposed region 47 of the imaging element substrate 4.

In the imaging element substrate 4 illustrated in FIG. 8, the conductor layer 52 exposed on the surface of the imaging element substrate 4 in the exposed region 47 is electrically connected to the first conductor layer 52a having the ground wiring pattern.

On the other hand, in the imaging element substrate 4 illustrated in FIG. 9, the conductor layer 52 exposed on the surface of the imaging element substrate 4 in the exposed region 47 may be the conductor layer 52 that is not electrically connected to the first conductor layer 52a.

Specifically, the conductor layer 52 exposed in the exposed region 47 may be a fourth conductor layer 52e having no wiring pattern or the conductor layer 52 electrically connected to the fourth conductor layer 52e in the imaging element substrate 4 illustrated in FIG. 9. The fourth conductor layer 52e having no wiring pattern is insulated from the other conductor layers 52 having the wiring patterns constituting the electric circuit of imaging element substrate 4. The fourth conductor layer 52e having no wiring pattern may be the conductor layer 52 dedicated to heat dissipation provided for transferring heat of the imaging element substrate 4 to the housing 1.

Here, the conductor layer 52 having the wiring pattern is, for example, the conductor layer 52 constituting the electric circuit that implements an electrical function of the imaging element substrate 4, such as the first conductor layer 52a to the third conductor layer 52c. On the other hand, the conductor layer 52 having no wiring pattern is, for example, the conductor layer 52 that does not constitute the electric circuit that implements the electrical function of the imaging element substrate 4, such as the fourth conductor layer 52e.

The conductor layer 52 having no wiring pattern is insulated from the conductor layer 52 having the wiring pattern.

Since the imaging element substrate 4 illustrated in FIG. 9 uses the conductor layer 52 dedicated to heat dissipation as the conductor layer 52 exposed in the exposed region 47, the electrical function of the imaging element substrate 4 can be secured more reliably.

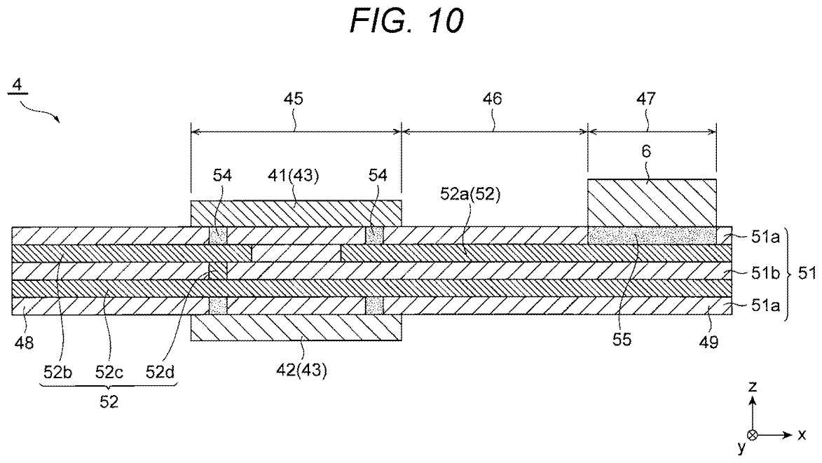

FIG. 10 is a schematic diagram illustrating a second modification of the exposed region 47 of the imaging element substrate 4.

In the imaging element substrate 4 illustrated in FIG. 8, the surface of the conductor layer 52 exposed in the exposed region 47 is in direct contact with the intermediate member 6. On the other hand, the surface of the conductor layer 52 exposed in the exposed region 47 may be covered with a bonding material 55 in the imaging element substrate 4 illustrated in FIG. 10. The bonding material 55 is a bonding material such as solder that has a high thermal conductivity and is capable of being bonded to the conductor layer 52. In the imaging element substrate 4 illustrated in FIG. 10, the surface of the bonding material 55 is in contact with the intermediate member 6.

When the conductor layer 52 made of a copper foil or the like is exposed on the surface of the imaging element substrate 4, corrosion and electrolytic corrosion are likely to occur in the conductor layer 52, which may affect the life of the imaging element substrate 4. Since the surface of the conductor layer 52 exposed in the exposed region 47 is covered with the bonding material 55 in the imaging element substrate 4 illustrated in FIG. 10, it is possible to suppress the corrosion and electrolytic corrosion of the exposed conductor layer 52. The imaging element substrate 4 illustrated in FIG. 10 can extend the life of the imaging element substrate 4.

Further, the bonding material 55 may be the same as the bonding material 54 that bonds the electronic component 43 and the conductor layer 52 in the mounting region 45. In this case, the bonding material 55 is added to the conductor layer 52 in the exposed region 47 as part of the process of mounting the electronic component 43 on the imaging element substrate 4. When the bonding material 54 and the bonding material 55 are the same solder, a reflow-type solder bonding process is performed as the process of mounting the electronic component 43 on the imaging element substrate 4. In this case, when the solder used as the bonding material 54 is applied to the imaging element substrate 4, the conductor layer 52 in the exposed region 47 can be covered with the bonding material 55 only by applying the solder to the conductor layer 52 in the exposed region 47. The imaging element substrate 4 illustrated in FIG. 10 can extend the life of the imaging element substrate 4 without increasing the number of steps of the mounting process.

<Others>

Note that the present invention is not limited to the above-described embodiments, and includes various modification examples. For example, the above-described embodiments have been described in detail in order to describe the present invention in an easily understandable manner, and are not necessarily limited to one including the entire configuration that has been described above. Further, some configurations of a certain embodiment can be substituted by configurations of another embodiment, and further, a configuration of another embodiment can be added to a configuration of a certain embodiment. Further, addition, deletion or substitution of other configurations can be made with respect to some configurations of each embodiment.

Further, a part or all of each of the above-described configurations, functions, processing units, processing means, and the like may be realized, for example, by hardware by designing with an integrated circuit and the like. Further, the above-described respective configurations, functions and the like may be implemented by software by the processor interpreting and executing a program for implementing the respective functions. Information such as programs, tapes, and files that realize the respective functions can be installed in a storage device such as a memory, a hard disk, and a solid state drive (SSD), or a storage medium such as an IC card, an SD card, and a DVD.

Further, only a control line and an information line considered to be necessary for the description have been illustrated, and all control lines and information lines required for a product are not illustrated. It may be considered that most of the configurations are practically connected to each other.

### REFERENCE SIGNS LIST

1 housing
16 connection portion
3 lens unit
4 imaging element substrate
41 imaging element
43 electronic component
45 mounting region
46 covered region
47 exposed region
48 first end portion
49 second end portion
51 insulating layer
52 conductor layer
54 bonding material
55 bonding material
6 intermediate member
7 signal processing substrate
71 first circuit element
72 second circuit element
73 third circuit element
100 imaging device
OA optical axis

1. An imaging device comprising:
an imaging element substrate on which an insulating layer and a conductor layer are stacked and an imaging element is mounted; and
a housing which accommodates the imaging element substrate,
wherein a surface of the imaging element substrate has a mounting region on which an electronic component including the imaging element is mounted, a covered region in which the conductor layer is covered with the insulating layer, and an exposed region in which the conductor layer is exposed from the insulating layer, and
the exposed region is connected to the housing.

2. The imaging device according to claim 1, further comprising
a signal processing substrate which is arranged to face a back surface of the imaging element substrate and on which a circuit element that processes an output signal of the imaging device is mounted, the back surface being opposite to a front surface of the imaging element substrate on which the imaging element is mounted,
wherein the imaging element substrate includes a pair of imaging element substrates arranged with an interval in a direction along the front surface,
the circuit element is arranged between the pair of imaging element substrates as viewed from an optical axis direction of a lens unit that forms a subject image on the imaging element,
each of the pair of imaging element substrates has a first end portion located in an outward direction from the circuit element toward the imaging element as viewed from the optical axis direction, and a second end portion located on an outer side of the first end in the outward direction, and
the exposed region is provided in the second end portion of each of the pair of imaging element substrates, and is connected to an end portion located in the outward direction of the housing.

3. The imaging device according to claim 2, wherein
the exposed region is connected to the housing through an intermediate member having thermal conductivity.

4. The imaging device according to claim 3, wherein
the second end portion of the imaging element substrate provided with the exposed region is arranged on an outer side of an end portion located in the outward direction of the signal processing substrate.

5. The imaging device according to claim 4, wherein
the housing includes a pair of connection portions to which the exposed regions of the pair of imaging element substrates are connected,
the pair of connection portions is orthogonal to the optical axis direction and is arranged with an interval in a direction along the front surface,
the exposed region of each of the pair of imaging element substrates is orthogonal to the optical axis direction and is arranged to face each of the pair of connection portions with an interval in the optical axis direction, and
the intermediate member is provided for the interval between the exposed region of each of the pair of imaging element substrates and each of the pair of connection portions.

6. The imaging device according to claim 1, wherein
the electronic component is mounted on the imaging element substrate using a bonding material in the mounting region, and
a surface of the conductor layer exposed to the surface of the imaging element substrate is covered with the bonding material in the exposed region.
